(19) United States
(12) Patent Application Publication
(10) Pub. No.: US 2015/0004088 A1
(43) Pub. Date: Jan. 1, 2015

(54) Thermoelectric Material Based on Oxide Coated Nanocrystals

(71) Applicant: Evident Technologies, Troy, NY (US)

(72) Inventors: Clinton T. Ballinger, Burnt Hills, NY (US); Bed Poudel, Newtonville, MA (US)

(21) Appl. No.: 14/317,705

(22) Filed: Jun. 27, 2014

Related U.S. Application Data
(60) Provisional application No. 61/840,645, filed on Jun. 28, 2013.

(51) Int. Cl. H01L 35/16; H01L 35/22; H01L 35/34

(52) U.S. Cl. CPC H01L 35/16; H01L 35/34; H01L 35/22
USPC 423/304; 427/58; 264/104; 264/434; 423/579; 423/509; 423/512.1

(57) ABSTRACT

Disclosed herein is an oxide coated semiconductor nanocrystal population and a method of synthesizing the oxide coated semiconductor nanocrystal population. The method includes coating a semiconductor nanocrystal population with a species capable of being oxidized to create a coated semiconductor nanocrystal population. The method further includes exposing the coated semiconductor nanocrystal population to oxygen to create the oxide coated semiconductor nanocrystal population. Further disclosed herein is a consolidated material and a method of consolidating a material from the oxide coated semiconductor nanocrystal population.

### CROSS-REFERENCE TO RELATED APPLICATIONS

This application claims the benefit of co-pending U.S. Provisional Application Ser. No. 61/840,645, filed 28 Jun. 2013, which is hereby incorporated by reference herein.

### FIELD OF THE INVENTION

Embodiments of the present invention relate generally to a composition of matter containing oxide coated nanoscale semiconductor particles and methods of providing an oxide coating on a population of semiconductor nanocrystals in order to provide a grain growth inhibitor useful for consolidation of the nanocrystals, which can enhance the thermoelectric properties of the consolidated material.

### BACKGROUND OF THE INVENTION

Recent research has focused on the use of different types of nanoparticles as a starting material for making thermoelectric materials. It is believed that nanoparticles can enhance the performance of thermoelectric materials. It is generally believed that the small particles of a nanoscale starting material can result in a small grain size of a consolidated material. The small grain size may lead to low thermal conductivity and thus, an enhanced thermoelectric figure of merit.

However, consolidation of nanoscale powders typically requires a level of heat and pressure that often results in grain growth within the consolidated material. For instance, BiTe-based semiconductor nanocrystals, a common thermoelectric material, has a tendency to rapidly grow in terms of grain size when exposed to elevated temperatures. Thus, consolidation of these types of materials can often result in an undesirably large grain structure, defeating the purpose of using nanoscale starting materials.

### BRIEF DESCRIPTION OF THE INVENTION

Embodiments of the invention disclosed herein may include a method of synthesizing an oxide coated semiconductor nanocrystal population, the method comprising: coating a semiconductor nanocrystal population with a species capable of being oxidized to create a coated semiconductor nanocrystal population; and exposing the coated semiconductor nanocrystal population to oxygen to create the oxide coated semiconductor nanocrystal population.

Embodiments of the invention may also include an oxide coated semiconductor nanocrystal population synthesized using a method, the method comprising: coating a semiconductor nanocrystal population with a species capable of being oxidized to create a coated semiconductor nanocrystal population; and exposing the coated semiconductor nanocrystal population to oxygen to create the oxide coated semiconductor nanocrystal population.

Embodiments of the invention may also include a consolidated material made by a method, the method comprising: obtaining an oxide coated semiconductor nanocrystal population; and consolidating the oxide coated semiconductor nanocrystal population.

Embodiments of the invention may also include a composition of matter comprising: a semiconductor nanocrystal population; and an oxide coating surrounding an outer surface of each semiconductor nanocrystal of the semiconductor nanocrystal population.

### BRIEF DESCRIPTION OF THE DRAWINGS

FIG. 1 shows an example flow diagram according to embodiments of the invention.

### DETAILED DESCRIPTION OF THE INVENTION

Embodiments of the present invention include inhibiting grain growth via an oxide layer introduced on an outside surface of the nanocrystals and incorporated before they are fully consolidated. The introduced oxide layer can act as a grain growth inhibitor, as well as an electron energy filter, as will be further described below.

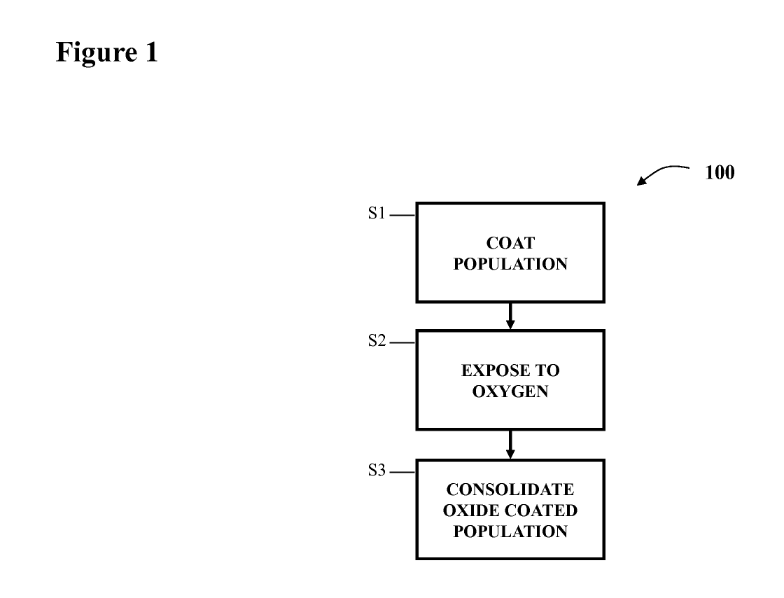

In one embodiment, a method of synthesizing an oxide coated semiconductor nanocrystal population is disclosed. The method 100, as illustrated in FIG. 1, may include coating a semiconductor nanocrystal population with a species capable of being oxidized in order to create a coated semiconductor nanocrystal population (S1). The semiconductor nanocrystal population can include any now known or later developed species of semiconductor nanocrystals, including but not limited to quantum dots. The nanocrystals may be produced by any known means. For instance, colloidal synthesis, ball milled semiconductors, and many other methods can be utilized to create a nanocrystal species. However, as an artifact of the type of material, these nanocrystals, which may be in the form of a dried powder, are typically susceptible to grain growth whenever heated or put under pressure. This is at least partially due to the fact that the atomic species within the nanoparticles are frequently mobile enough to move around while heated, resulting in grain growth arising at least partially from the close proximity of the separate nanocrystals of the population of nanocrystals.

It is known in the art that these nanocrystals can be coated with different types of materials. For instance, monolayers of a different material, or even thicker layers, can be added to an outside surface of some or all of the nanocrystals. In some embodiments of the disclosure, an outer surface of the nanocrystals may be coated in a species which is capable of easily being oxidized. In one embodiment, this species may include an atomic species. In such an embodiment, the atomic species may be chosen from a group which can include phosphorous, sulfur, and tellurium. It should be understood that any atomic species which easily undergoes oxidation may be utilized. In an alternative embodiment, the species may include a molecular species. For instance, the molecular species can include tri-octyl phosphine or other moieties capable of easily being oxidized. A number of molecular moieties, which may also act as a ligand structure, may undergo oxidation relatively easily and are intended to be included in the spirit of the disclosure. It should be understood that a single atomic species or a combination of different atomic species may be used together. The same is true for the molecular species. In some embodiments, a combination of atomic species and molecular species may be utilized to coat the surface of the population of nanocrystals.

Following coating of the semiconductor nanocrystal species, the coated nanocrystals may then be exposed to oxygen in order to create the oxide coated semiconductor nanocrystal population (S2). In many previous experiments, exposure to oxygen has been viewed as having a negative affect on nanocrystals, due to the reduced quantum confinement effects on the material. However, it has been discovered that oxidation according to the disclosed embodiments allows the oxide coating of the semiconductor nanocrystal population to act as a grain growth inhibitor. Any method of oxygen exposure may be utilized. For instance, common synthesis procedures are frequently carried out in a glove box or under inert gas atmospheres. In some embodiments of the present invention, the gas in the glove box or system supplying inert gas can be replaced briefly with oxygen in order to expose the nanocrystal population to oxygen. In another embodiment, the population of nanocrystals may be removed from the synthesis environment and simply exposed to oxygen present in the air. This exposure time is typically quite brief, as the species is quick to undergo oxidation. Exposure time may include any amount of time from a few seconds up to a couple of hours.

Once exposed to oxygen, an oxide coating can form on the outer surface of the nanocrystals, effectively coating the nanocrystal in an oxide layer. This oxide layer has been found to provide grain growth inhibition when the nanocrystals are consolidated. For instance, with the use of phosphorous, an oxide of phosphorous can develop on the surface of the nanocrystals. In one example, P₂O₅ has been found to form a coating on the outside surface of each nanocrystal of the population. This coating has been found to inhibit grain growth quite effectively.

Once the coating has been formed, the oxide coated nanocrystals can be consolidated by any means now known or later developed (S3). For instance, consolidation may include the use of heat, pressure, a combination of heat and pressure, spark plasma sintering, or any combination thereof. After consolidation, it has been found that the grain size of the oxide coated nanocrystals remains substantially similar to the starting material, due at least in part to the grain growth inhibiting oxide coating. A further advantage that has been discovered includes that the oxide may actually serve as an electron filter for the consolidated material. In stark contrast, an oxide coating has previously been considered a negative aspect as an electron insulator in previous attempts. In embodiments of the current invention where the oxide coating works as an electron filter, low energy electrons may be filtered out, allowing high energy electrons to pass with more preference. This feature can affect the low level electrons, effectively filtering any electrons with insufficient energy to jump the band gap. Accordingly, the oxide may act as an electron filter increasing the efficiency of the consolidated material according to embodiments of the disclosure.

It should be understood that further embodiments include not only the method of making the oxide coated nanocrystals and the method of consolidating said coated nanocrystals, but an oxide coated semiconductor nanocrystal population made according to the disclosed methods and a consolidated material made according to the disclosed methods.

The foregoing description of various aspects of the invention has been presented for the purpose of illustration and description. It is not intended to be exhaustive or to limit the invention to the precise form disclosed, and obviously, many modifications and variations are possible. Such variations and modifications that may be apparent to one skilled in the art are intended to be included within the scope of the present invention as defined by the accompanying claims.

What is claimed:

1. A method of synthesizing an oxide coated semiconductor nanocrystal population, the method comprising:
coating a semiconductor nanocrystal population with a species capable of being oxidized to create a coated semiconductor nanocrystal population; and
exposing the coated semiconductor nanocrystal population to oxygen to create the oxide coated semiconductor nanocrystal population.

2. The method of claim 1, wherein the species includes an atomic species.

3. The method of claim 2, wherein the atomic species is chosen from a group consisting of: phosphorous, sulfur, and tellurium.

4. The method of claim 1, wherein the species includes a molecular species.

5. The method of claim 4, wherein the molecular species includes tri-octyl phosphine.

6. The method of claim 1, wherein an oxide coating of the oxide coated semiconductor nanocrystal population acts as a grain growth inhibitor.

7. The method of claim 1, further comprising:
consolidating the oxide coated semiconductor nanocrystal population.

8. The method of claim 7, wherein the consolidation is achieved using heat, pressure, or a combination of heat and pressure.

9. The method of claim 7, wherein the consolidation includes spark plasma sintering.

10. An oxide coated semiconductor nanocrystal population synthesized using a method, the method comprising:
coating a semiconductor nanocrystal population with a species capable of being oxidized to create a coated semiconductor nanocrystal population; and
exposing the coated semiconductor nanocrystal population to oxygen to create the oxide coated semiconductor nanocrystal population.

11. The oxide coated semiconductor nanocrystal population of claim 10, wherein the species includes an atomic species.

12. The oxide coated semiconductor nanocrystal population of claim 11, wherein the atomic species is chosen from a group consisting of: phosphorous, sulfur, and tellurium.

13. The oxide coated semiconductor nanocrystal population of claim 10, wherein the species includes a molecular species.

14. The oxide coated semiconductor nanocrystal population of claim 13, wherein the molecular species includes tri-octyl phosphine.

15. The oxide coated semiconductor nanocrystal population of claim 10, wherein an oxide coating of the oxide coated semiconductor nanocrystal population acts as a grain growth inhibitor.

16. A consolidated material made by a method, the method comprising:
obtaining an oxide coated semiconductor nanocrystal population; and
consolidating the oxide coated semiconductor nanocrystal population.

17. The consolidated material of claim 16, wherein the consolidation is achieved using heat, pressure, or a combination of heat and pressure.

18. The consolidated material of claim 16, wherein the consolidation includes spark plasma sintering.

19. A composition of matter comprising:
a semiconductor nanocrystal population; and
an oxide coating surrounding an outer surface of each semiconductor nanocrystal of the semiconductor nanocrystal population.
